(19) United States
(12) Patent Application Publication
(10) Pub. No.: US 2023/0207660 A1
(43) Pub. Date: Jun. 29, 2023

(54) 3D SINGLE CRYSTAL SILICON TRANSISTOR DESIGN INTEGRATED WITH 3D WAFER TRANSFER TECHNOLOGY AND METAL FIRST APPROACH

(71) Applicant: Tokyo Electron Limited, Tokyo (JP)

(72) Inventors: Mark I. GARDNER, Cedar Creek, TX (US); H. Jim FULFORD, Marianna, NY (US); Partha MUKHOPADHYAY, Oviedo, FL (US)

(73) Assignee: Tokyo Electron Limited, Tokyo (JP)

(21) Appl. No.: 17/957,076

(22) Filed: Sep. 30, 2022

Related U.S. Application Data
(60) Provisional application No. 63/294,481, filed on Dec. 29, 2021.

(51) Int. Cl. H01L 29/66; H01L 27/12; H01L 29/06; H01L 29/423; H01L 29/417; H01L 29/775; H01L 21/762; H01L 29/40

(52) U.S. Cl. CPC H01L 29/66439; H01L 27/1203; H01L 29/0676; H01L 29/42392; H01L 29/41733; H01L 29/775; H01L 21/76251; H01L 29/401

(57) ABSTRACT

A method of forming a vertical channel transistor includes forming a first source-drain (SD) contact on a first surface of a semiconductor device layer; and forming a second SD contact layer on a second surface of the semiconductor device layer, the second surface being opposite to the first surface. The semiconductor device layer is pattern etched to form a vertical channel structure having a first end connected to the first SD contact and a second end opposite to the first end and connected to the second SD contact. A gate-all-around (GAA) structure is formed to completely surrounding at least a portion of the vertical channel structure at a position between the first SD contact and the second SD contact.

### INCORPORATION BY REFERENCE

This present disclosure claims the benefit of U.S. Provisional Application No. 63/294,481, titled 3D SINGLE CRYSTAL SILICON TRANSISTOR DESIGN INTEGRATED WITH 3D WAFER TRANSFER TECHNOLOGY AND METAL FIRST APPROACH filed on Dec. 29, 2021, which is incorporated herein by reference in its entirety.

### TECHNICAL FIELD

The present disclosure generally relates to microelectronic devices including semiconductor devices, transistors, and integrated circuits, including methods of microfabrication.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

### SUMMARY

The present disclosure is directed to forming one or more tiers of vertical channel transistors by various techniques including the following aspects of the present disclosure.

An aspect 1 provides a method of forming a vertical channel transistor, comprising: forming a first source-drain (SD) contact on a first surface of a semiconductor device layer; forming a second SD contact layer on a second surface of the semiconductor device layer, the second surface being opposite to the first surface; pattern etching the semiconductor device layer to form a vertical channel structure having a first end connected to the first SD contact and a second end opposite to the first end and connected to the second SD contact; and forming a gate-all-around (GAA) structure completely surrounding at least a portion of the vertical channel structure at a position between the first SD contact and the second SD contact.

Aspect 2 includes the method of claim 1 further comprising: providing a silicon-on-insulator (SOI) substrate having a bulk semiconductor layer, an insulating layer covering the bulk semiconductor layer and the semiconductor device layer covering the insulating layer, wherein the first surface of the device layer provides a working surface of the SOI substrate; after depositing the first SD contact on the SOI substrate, bonding the SOI substrate with another substrate having a dielectric layer such that the first SD contact faces the dielectric layer; and removing the bulk semiconductor layer and insulating layer of the SOI substrate to expose the second surface of the semiconductor device layer.

Aspect 3 includes the method of claim 1, wherein at least one of the forming a first SD contact and forming a second SD contact includes forming a doped silicon layer on the semiconductor device layer; forming a metal layer on the doped silicon layer; and annealing the semiconductor device layer, doped silicon layer and metal layer to form a silicide layer between the doped silicide layer and the metal layer.

Aspect 4 includes the method of claim 1, wherein the pattern etching includes directionally etching the semiconductor device layer to form a vertical channel structure.

Aspect 5 includes the method of claim 1, wherein the forming a GAA structure includes: forming a gate dielectric layer completely surrounding at least a portion of the vertical channel structure at a position between the first SD contact and the second SD contact; and forming a gate metal layer completely surrounding the gate dielectric layer.

Aspect 6 includes the method of claim 5, wherein: the forming a gate dielectric layer includes performing atomic layer deposition (ALD) of the gate dielectric layer; and the forming a gate metal layer includes performing ALD of the gate metal layer.

Aspect 7 includes the method of claim 6, further including directionally etching the gate metal layer to form the GAA structure.

Aspect 8 includes the method of claim 1, further including: forming a first metal connection to the second SD contact; and forming a second metal connection to the GAA structure.

Aspect 9 includes the method of claim 1, wherein the forming a first SD contact includes forming a metal routing layer connected to the first SD contact.

Aspect 10 includes the method of claim 1, wherein the vertical channel transistor is a lower tier transistor formed in a formed in a lower tier of side-by-side vertical channel transistors.

Aspect 11 includes the method of claim 10, further including forming an upper tier vertical channel transistor in an upper tier of side-by-side vertical channel transistors provided over the lower tier of transistors, wherein at least one upper tier vertical channel transistor is electrically connected to the lower tier transistor.

Aspect 12 includes the method of claim 11, further including forming an interconnect layer between the lower tier and the upper tier of vertical channel transistors.

Aspect 13 includes the method of claim 10 further including: providing an upper SOI substrate having an upper tier SD contact formed in an Si device layer of the upper SOI substrate; bonding the upper SOI substrate with the lower tier of transistors; and removing a bulk semiconductor layer and an insulating layer of the upper SOI substrate.

Aspect 14 includes the method of claim 13, further including forming vertical channel structures of the upper tier of transistors from the Si device layer of the upper SOI substrate.

Another aspect 15 provides a method of microfabrication, the method including: forming a first metal wiring layer on a semiconductor surface of a first wafer, the first wafer being a semiconductor-on-insulator wafer, the semiconductor-on-insulator having a first semiconductor layer formed on a first dielectric layer, the first dielectric layer formed on first bulk semiconductor material, the first metal wiring layer being in electrical contact with the first semiconductor layer; bonding the first wafer to a second wafer resulting in a bonded wafer, the second wafer having a second dielectric layer formed on a second bulk semiconductor material, the first metal wiring layer of the first wafer being bonded to the second dielectric layer of the second wafer; removing the first bulk semiconductor material and the first dielectric layer from the bonded wafer; patterning and etching the first semiconductor layer to form channel structures from the first semiconductor material, the first semiconductor layer being etched until uncovering the first wiring layer; and forming gate structures all around a cross section of the respective channel structures to form side-by-side vertical channel transistors a current flow direction perpendicular to the first metal wiring layer.

Aspect 16 includes the method of claim 15, wherein forming the first metal wiring layer includes forming first metal silicide interface prior to wafer bonding.

Aspect 17 includes the method of claim 16, further including forming a second silicide interface on ends of the channel structures opposite the first metal wiring layer, wherein the second silicide interface is formed prior to forming the gate structures.

Aspect 18 includes the method of claim 17, further including forming a second wiring layer over the bonded substrate, the second wiring layer being in electrical contact with the channels, the channels positioned in between the first wiring layer and the second wiring layer.

Aspect 19 includes the method of claim 15, wherein the side-by-side vertical channel transistors are formed in a lower tier of vertical channel transistors.

Aspect 20 includes the method of claims 19, further including: forming at least one upper tier of vertical channel transistors on the lower tier of vertical channel transistors by bonding at least one SOI substrate to the lower tier of vertical transistors; and forming upper tier vertical channel transistors from an Si device layer of the at least one SOI substrate, wherein each of the at least one SOI substrates corresponds to a respective upper tier of vertical channel transistors.

### BRIEF DESCRIPTION OF THE DRAWINGS

Various embodiments of this disclosure that are proposed as examples will be described in detail with reference to the following figures, wherein like numerals reference like elements, and wherein:

FIGS. 1, 2, 3, 4, 5 and 6 are sectional views of intermediate structures in a process for manufacturing vertical channel transistors in accordance with an example embodiment of the disclosed invention;

FIG. 7 is a perspective view of a lower tier of side-by-side vertical channel transistors formed by the process of FIGS. 1-6; and

FIGS. 8, 9, 10, 11 and 12 are sectional views of intermediate structures in a process for manufacturing an upper tier of vertical channel transistors in accordance with an example embodiment of the disclosed invention.

### DETAILED DESCRIPTION OF EMBODIMENTS

As noted in the Background, 3D integration for logic chips, GPUs, FPGAs, and SoC for example is being pursued. Techniques disclosed herein include methods of microfabrication of vertical channel transistors. 3D invention stacking is an important innovation for high performance CMOS that may be integrated in current manufacturing processes. Techniques herein use a Silicon Transfer Design, which facilitates 3D devices to be used with high mobility channels. Both CFET and side-by-side transistors are anticipated to go into volume production in the near future. A feature of this disclosure is a metal stack underneath the Source transistor region, and such metal stack may also be used for an additional routing layer. Because of using a bonding approach, techniques herein can be used with present high volume manufacturing to make 3D devices with a built in routing layer. Both intrinsic channel devices and doped channel regions are enabled by techniques herein. Different source-drain (SD) metals and gate electrode materials can be used to optimize both the NMOS and PMOS devices for high performance.

Embodiments will now be described with reference to the figures. One embodiment provides for wafer transfer with an oxide-to-oxide bond. A metal first layer design for fabricating transistors with silicon nanosheet may be used, wherein alignment offset has little or no effect on device performance. An intrinsic silicon wafer may be used and implant later to provide a junction transistor. Alternatively, a lightly doped silicon wafer and implant with opposite polarity to have junction transistor. In some embodiments, n-number stacks of Si nanosheet devices are provided by wafer transfer. Polarity of the stack can be varied as p-type or n-type. Different High-k, Gate metal as well as SD metal can be used as options.

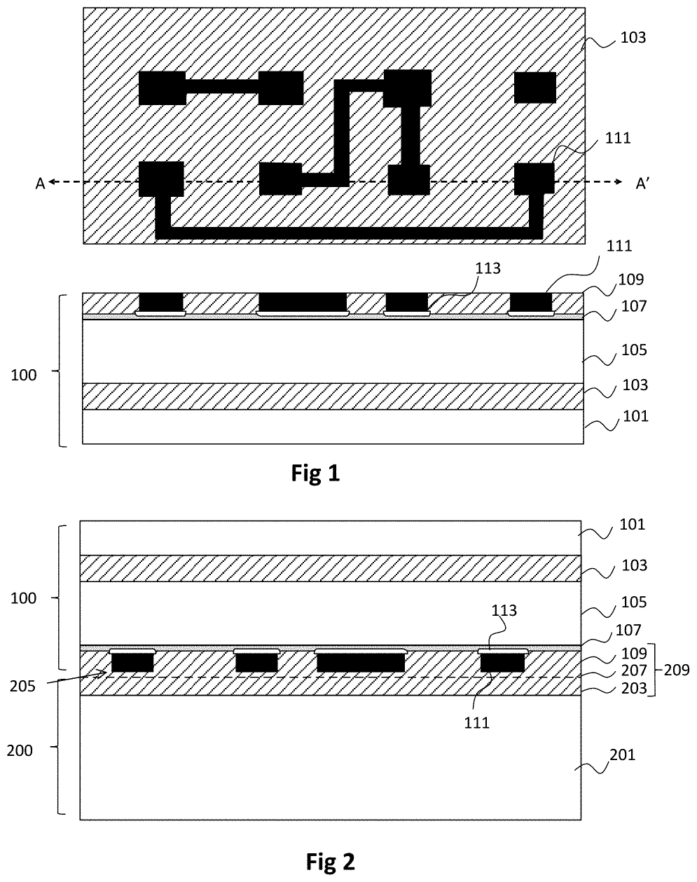

FIGS. 1-12 illustrate an example process flow. FIGS. 1-12 show intermediate structures in a process flow according to embodiments of the disclosed invention. FIG. 1 shows top and cross-sectional views of an intermediate structure after formation of first SD contacts of vertical channel transistors.

The process begins by providing a Si (silicon) device layer as the top surface of an SOI (silicon-on-insulator) Si substrate. As shown in FIG. 1, the SOI substrate includes base Si layer 101, insulating layer 103 and Si device layer 105 which serves as the working surface of the substrate for the process. SD contacts and a metal interconnect layer are formed on the top surface of the SOI substrate. In the example embodiment of FIG. 1, a layer of doped Si material 107 is provided on the Si layer 105 by ion implantation of the Si layer 105, for example. Alternatively, the doped Si layer 107 may be formed by deposition, epitaxial growth or other known methods. The dopant may be n-type or p-type. A dielectric layer 109 is deposited on the doped Si layer 107, and photolithography and etch processes are performed to form pattern openings in the dielectric 109 for the metal wiring layer and SD contacts. The doped Si layer 107 serves as an etch stop such that the pattern exposes regions of the doped Si layer 107. After stripping photoresist, fill metal 111 is deposited in the pattern openings in the dielectric 109, and CMP (planarize via chemical-mechanical polishing) is performed. The substrate is then annealed to form silicide 113 at an interface of the doped Si material 107 and metal 111 as shown in FIG. 1.

The SOI substrate 100 having metal interconnect layer thereon is then bonded with another substrate 200 as shown in FIG. 2. The SOI substrate 100 is flipped over and the metal interconnect side is bonded with substrate 200 having Si layer 201 and dielectric layer 203 thereon. In the embodiment of FIG. 2, additional dielectric is added to the dielectric 109 to cover the SD contact and metal routing layer prior to bonding as shown by arrow 205. Bonding interface is 207 is shown between the dielectrics 109 and 203 which form bonded dielectric 209. In some embodiments, the dielectric layers 109 and 203 are oxide layers and oxide-oxide bonding is performed to join the two Si wafers at a junction 207. In this embodiment, there is no concern about alignment of the SD contacts and metal wiring layer because the substrate 200 does not have metal patterns formed therein.

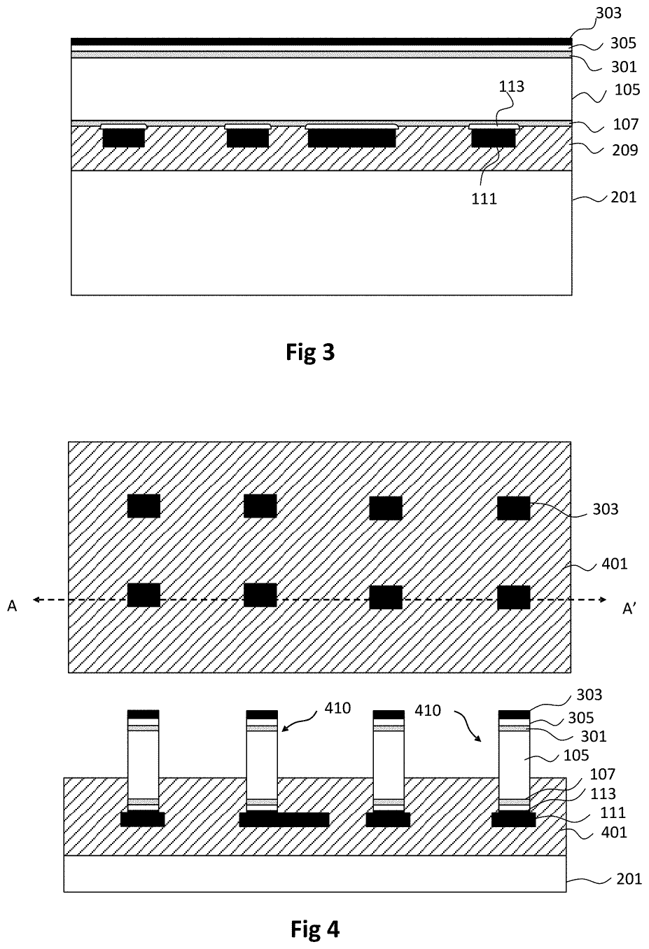

After bonding of the SOI substrate 100 with the substrate 200, the insulating layer 103 of the SOI substrate is etched to detach the base layer 101 and expose a back side of the Si device layer 105 which is opposite to the side on which the SD contacts and routing layer was formed. The SOI is etched and the top wafer removed naturally. The unpatterned backside of Si layer 105 is exposed as a working surface for further processing. The backside of Si device layer 105 is implanted with a dopant to form a blanket layer of doped Si 301 and metal 303 is formed on the doped Si layer. The dopant may be n-type or p-type. The substrate is then annealed to form a blanket layer of silicide 305 at an interface of the doped Si material 301 and metal 303 as shown in FIG. 3.

Vertical channel regions and additional SD contacts are then formed from the bonded substrate as shown in FIG. 4. A nanosheet mask pattern is used to directionally etch the metal 303, silicide 305, doped Si 301, Si layer 105, doped Si 107 and silicide 113 to form the vertical channel regions 410 from these layers. In some embodiments, the metal 111 can serve as an etch stop for the etch process forming the vertical channel regions 410. A fill dielectric is then deposited on the dielectric 209 provide a dielectric 401 coving the vertical channels 410, and CMP is performed. Etch of the dielectric 401 (self-aligned already) is then performed to expose sidewalls of the vertical channel structures 410. In the example embodiment t of FIG. 4, etching is performed to expose approximately two thirds the nanosheet vertical channels 410 as shown.

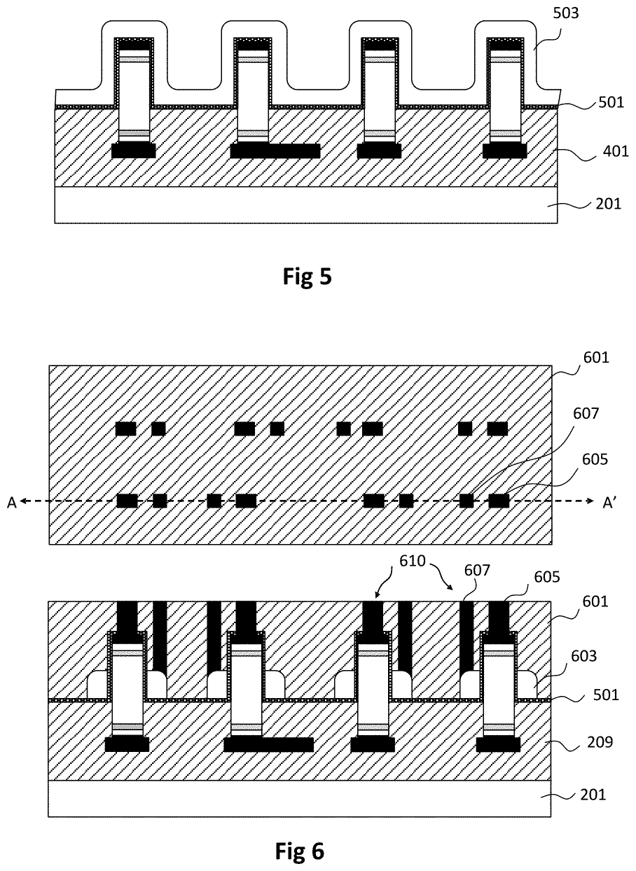

Materials for the gate structure are then deposited as shown in FIG. 5. In the example embodiment, atomic layer deposition (ALD) is used to deposit conformal layer of high-k dielectric 501 on the exposed vertical channel structures 410. ALD is then performed to form a conformal layer of gate metal 503 on the high-k material as shown in FIG. 5. The gate metal layer 503 is then directionally etched to clear the top part of the vertical channels for SD connections, and to remove metal in regions between vertical channels 410 to isolate adjacent devices. FIG. 6 shows the gate-all-around (GAA) structures 603 formed by the directional etch to provide side-by-side vertical channel transistors 610. A fill dielectric 601 covers the GAA structures 603 and vertical channels, and CMP is performed to prepare for further pattern etching. Dielectric 601 is patterned by photolithography to form openings for SD and gate connections. Etch of dielectric 601 and high-k dielectric 501 is performed with etch stop on metal SD contact metal 303 and GAA metal 603. After stripping of photoresist, fill metal is deposited in the openings and CMP is performed to form SD connection 605 and GAA connection 607 as shown in FIG. 6. The routing design for SD connection 605 and GAA connection 607 provides one example for illustration only, and other routing designs may be used. Any metal (e.g., different work function) can be used for SD contact metal 111 and 303, and gate metal 603 based on the application.

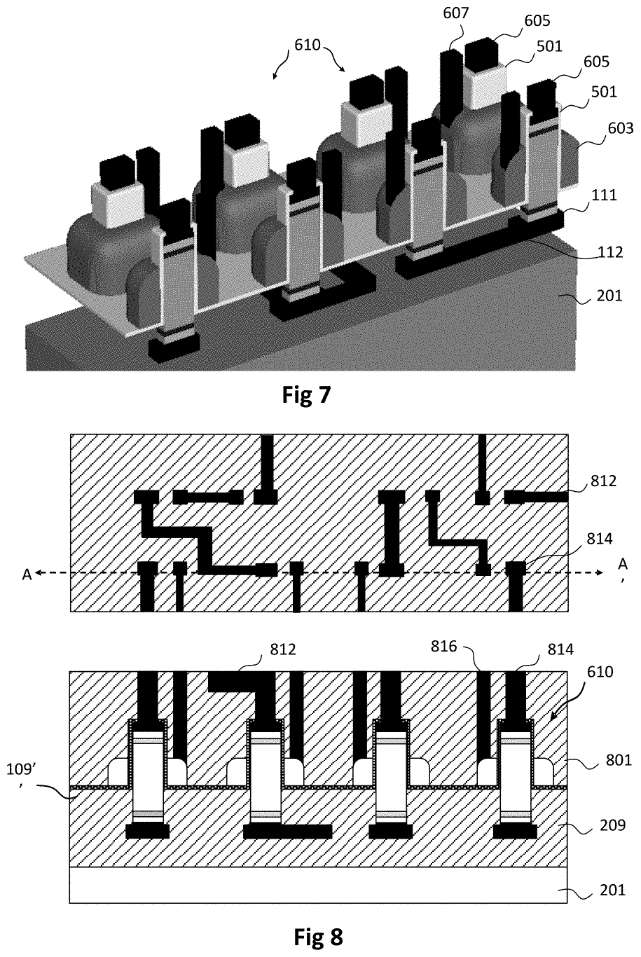

FIG. 7 provides a perspective view of a lower tier of side-by-side vertical channel transistors 610. The dielectric layers 209 and 601 are removed for clarity. With the intrinsic Si material of the vertical channel 105 described above, the n-type dopants of 107 and 301 may be diffused into the vertical channel 105 to form a junctionless transistor. In some embodiments, the intrinsic Si material of channels 105 may be replaced by doped Si (e.g., mildly doped p-type Si) to form junction transistors with the n-type layers 107 and 301.

In some embodiments, additional tiers of vertical transistor devices may also be formed as illustrated in the examples of FIGS. 8-12. First additional dielectric 801 is deposited on the first tier of devices as shown in FIG. 8. Dielectric 801 is patterned using interconnect routing mask with etch stop on metal. This layer allows to connect SDs and gates to the outer pad as well as interconnect as per circuit design requirement. Fill metal is deposited in the openings and CMP is performed to form interconnects 812, 814 and 816 as shown in FIG. 8. Any type of metal line can be used.

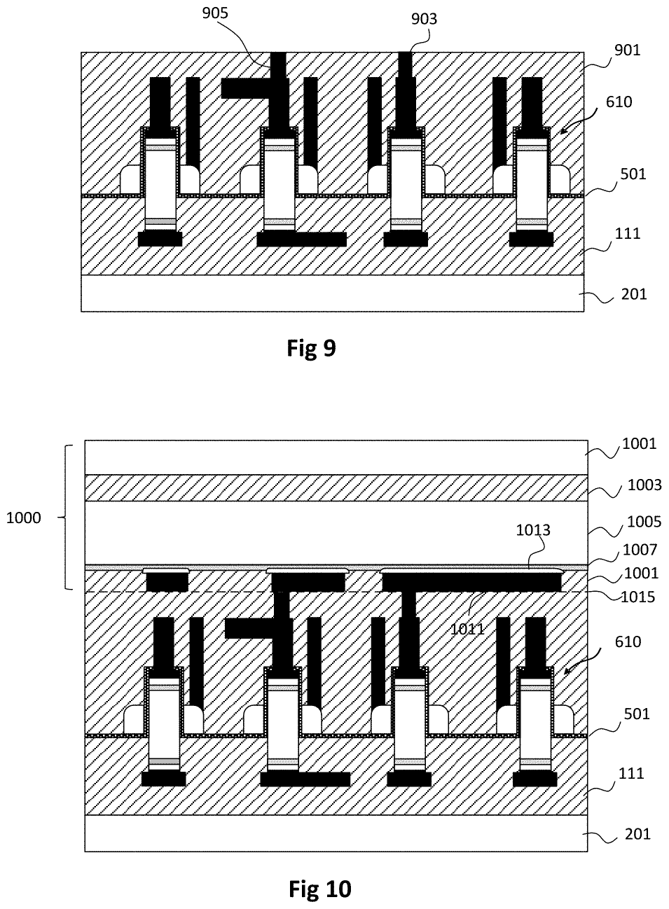

Dielectric 901 is deposited to cover the interconnect metal 812, 814 and 816, and the dielectric 901 is patterned using via mask to etch via openings in the dielectric. Via etch is stopped on the metal of the interconnect 812, 814 and 816. This will connect the bottom and top tiers of transistors and maintain hierarchy. Metal fill is deposited in the via openings to form vias 903 and 905, and CMP is performed to provide the structure of FIG. 9. Any type of metal line can be used. In some embodiments, the vias 903 and 905 are not limited in size to avoid the need for perfect alignment. Vias preferably have a wide scope of area to spread in the layer which can accommodate misalignment due to the wafer transfer of the hierarchical transistor layers. Via top pad size or the bottom metal layer pad size of hierarchical transistor set can be exercised to reduce or remove the misalignment effects.

The upper tier of transistors is provided by another Si device layer as the top surface of another SOI substrate. As shown in FIG. 10, the SOI substrate 1000 includes base Si layer 1001, insulating layer 1003 and Si device layer 1005 which serves as the working surface of the substrate for the process. SD contacts and a metal interconnect layer are formed from doped Si layer 1007 and metal layer 1011 with silicide layer 1013 therebetween in a similar manner as described in FIG. 1, and the SOI substrate 1000 having the SD contacts and metal routing layer thereon is bonded with the first tier substrate as shown in FIG. 10. Bonding interface is 1015 is also shown.

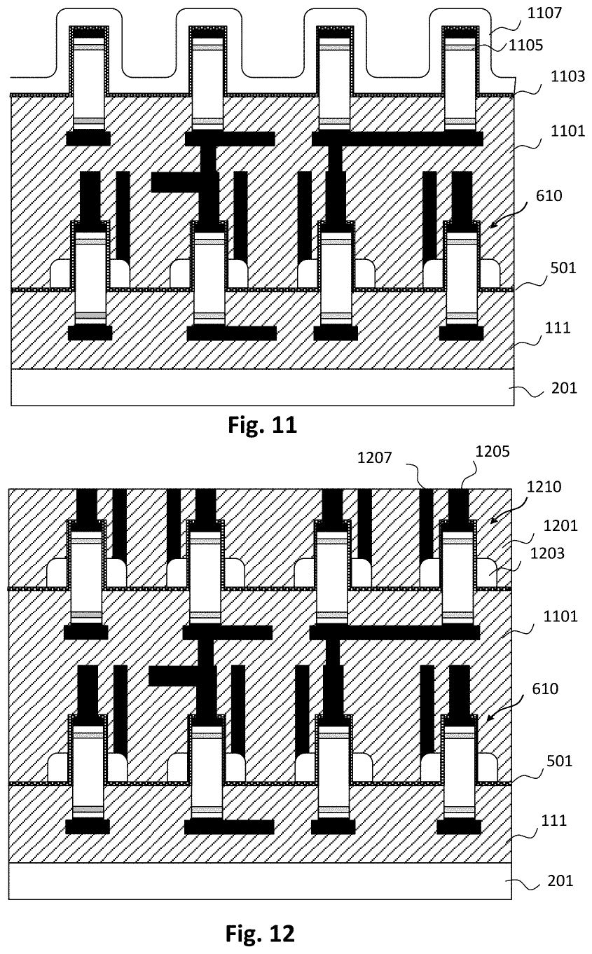

After bonding of the SOI substrate 1000 with the first tier substrate, the insulating layer 1003 is etched to detach the base layer 1001 and expose a back side of the Si device layer 1005. Doped Si, metal and silicide are then formed on the on the backside of Si device layer 1005, and vertical channels of the upper tier are formed in a similar process to that described in FIGS. 3 and 4. High-k layer 1103 and gate metal layer 1107 for the gate structure of the upper tier of devices is then formed to provide the structure shown in FIG. 11. The gate metal layer 1105 is then directionally etched to clear the top part of the vertical channels for SD connections, and to remove metal in regions between vertical channels to isolate adjacent devices of the upper tier of devices. SD connections 1205 and gate connections 1207 are then formed to complete the upper tier of transistors as shown in FIG. 12.

Doping concentrations in the upper tier of devices may be different from the lower tier of devices. For example, the Si 1005 of the upper tier may be lightly n-doped and p+-implanted layers 1007 and 1105 formed for junction transistors. With different polarity of Si in the lower and upper tiers of devices, different metal may be used for SD contacts of the lower and upper tier devices. Different gate metal may also be used to match with polarity of Si in the vertical channel.

The Si device layers and vertical channel structures may be made from semiconductor materials such as Si, Ge, SiGe, GaAs, InAs, InP , semiconductive behaving oxide (e.g. In₂O₃, SnO₂, InGaZnO, and ZnO, SnO), 2D material (e.g. WS₂, WSe₂, WTe₂, MoS₂, MoSe₂, MoTe₂, HfS₂, ZrS₂, TiS₂, GaSe, InSe, phosphorene, HfSe₂, ZrSe₂, HfZrSe₂, etc.) or any other suitable semiconductor material in monocrystalline and/or polycrystalline form. Further, the vertical channel structures may be doped with either p-type or n-type dopants at various doping concentration levels. The p-type dopant may be boron and the n-type dopant may be phosphorus or arsenic, however other suitable dopant materials may be used. Various techniques may be used to provide a strained channel material to improve carrier mobility, for example. In some embodiments, the vertical channel structure of the lower transistor tier and the vertical channel structure of the upper transistor tier may have the same material composition, but in other embodiments, the vertical channel structures can be different from one another. For example, both vertical channel structures may be NMOS, both vertical channel structures may be PMOS, or one of the vertical channel structures may be NMOS while the other vertical channel structure is PMOS.

The doped Si may also be made from any semiconductor material in monocrystalline or polycrystalline form and doped with either p-type or n-type dopants at various doping concentration levels. The SD regions of the lower and upper tiers of devices may be made of the same or different semiconductor materials from each other, and may be the same or a different material as their respective vertical channel structures. The SD regions may have the same or a different doping type as their respective vertical channel structures and may have the same or different doping concentration as their respective vertical channel structures. Various SD contact engineering techniques known in the semiconductor fabrication art may be employed in the design and formation of SD regions. For example, the S/D regions may include SD extensions.

Insulation and dielectric layers may be implemented as a dielectric material such as SiO, SiN, SiON, SiC, SiOC, SiCN, SiOCN, the like, or a combination thereof. These structures may also be implemented as high-k dielectrics. The same or different dielectric materials can be used for these structures. Device contacts, connections vias and the like may be made of any conductive material, such as a doped polysilicon material or a metal such as W, Co, Ru, Cu, Al, the like, or combinations thereof. The same or different conductor materials can be used for these structures.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present disclosure can be embodied and viewed in many different ways.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

What is claimed is:

1. A method of forming a vertical channel transistor, comprising:
forming a first source-drain (SD) contact on a first surface of a semiconductor device layer;
forming a second SD contact on a second surface of the semiconductor device layer, the second surface being opposite to the first surface;
pattern etching the semiconductor device layer to form a vertical channel structure having a first end connected to the first SD contact and a second end opposite to the first end and connected to the second SD contact; and
forming a gate-all-around (GAA) structure completely surrounding at least a portion of the vertical channel structure at a position between the first SD contact and the second SD contact.

2. The method of claim 1 further comprising:
providing a silicon-on-insulator (SOI) substrate having a bulk semiconductor layer, an insulating layer covering the bulk semiconductor layer and said semiconductor device layer covering the insulating layer, wherein the first surface of the semiconductor device layer provides a working surface of the SOI substrate;
after depositing the first SD contact on the SOI substrate, bonding the SOI substrate with another substrate having a dielectric layer such that the first SD contact faces the dielectric layer; and
removing the bulk semiconductor layer and insulating layer of the SOI substrate to expose the second surface of the semiconductor device layer.

3. The method of claim 1, wherein at least one of the forming a first SD contact and forming a second SD contact comprises:
forming a doped silicon layer on the semiconductor device layer;
forming a metal layer on the doped silicon layer; and
annealing the semiconductor device layer, doped silicon layer and metal layer to form a silicide layer between the doped silicon layer and the metal layer.

4. The method of claim 1, wherein the pattern etching comprises directionally etching the semiconductor device layer to form a vertical channel structure.

5. The method of claim 1, wherein the forming a GAA structure comprises:
forming a gate dielectric layer completely surrounding at least a portion of the vertical channel structure at a position between the first SD contact and the second SD contact; and
forming a gate metal layer completely surrounding the gate dielectric layer.

6. The method of claim 5, wherein:
the forming a gate dielectric layer comprises performing atomic layer deposition (ALD) of the gate dielectric layer; and
the forming a gate metal layer comprises performing ALD of the gate metal layer.

7. The method of claim 6, further comprising directionally etching the gate metal layer to form the GAA structure.

8. The method of claim 1, further comprising:
forming a first metal connection to the second SD contact; and
forming a second metal connection to the GAA structure.

9. The method of claim 1, wherein the forming a first SD contact comprises forming a metal routing layer connected to the first SD contact.

10. The method of claim 1, wherein the vertical channel transistor is a lower tier transistor formed in a formed in a lower tier of side-by-side vertical channel transistors.

11. The method of claim 10, further comprising forming an upper tier vertical channel transistor in an upper tier of side-by-side vertical channel transistors provided over the lower tier of transistors, wherein at least one upper tier vertical channel transistor is electrically connected to the lower tier transistor.

12. The method of claim 11, further comprising forming an interconnect layer between the lower tier and the upper tier of vertical channel transistors.

13. The method of claim 10 further comprising:
providing an upper SOI substrate having an upper tier SD contact formed in an Si device layer of the upper SOI substrate;
bonding the upper SOI substrate with the lower tier of transistors; and
removing a bulk semiconductor layer and an insulating layer of the upper SOI substrate.

14. The method of claim 13, further comprising forming vertical channel structures of the upper tier of transistors from the Si device layer of the upper SOI substrate.

15. A method of microfabrication, the method comprising:
forming a first metal wiring layer on a semiconductor surface of a first wafer, the first wafer being a semiconductor-on-insulator wafer, the semiconductor-on-insulator wafer having a first semiconductor layer formed on a first dielectric layer, the first dielectric layer formed on first bulk semiconductor material, the first metal wiring layer being in electrical contact with the first semiconductor layer;
bonding the first wafer to a second wafer resulting in a bonded wafer, the second wafer having a second dielectric layer formed on a second bulk semiconductor material, the first metal wiring layer of the first wafer being bonded to the second dielectric layer of the second wafer;
removing the first bulk semiconductor material and the first dielectric layer from the bonded wafer;
patterning and etching the first bulk semiconductor material to form channel structures from the first bulk semiconductor material, the first bulk semiconductor material being etched until uncovering the first wiring layer; and
forming gate structures all around a cross section of the respective channel structures to form side-by-side vertical channel transistors a current flow direction perpendicular to the first metal wiring layer.

16. The method of claim 15, wherein forming the first metal wiring layer includes forming first metal silicide interface prior to wafer bonding.

17. The method of claim 16, further comprising forming a second silicide interface on ends of the channel structures opposite the first metal wiring layer, wherein the second silicide interface is formed prior to forming the gate structures.

18. The method of claim 17, further comprising forming a second wiring layer over the bonded wafer, the second wiring layer being in electrical contact with the channels, the channels positioned in between the first metal wiring layer and the second wiring layer.

19. The method of claim 15, wherein the side-by-side vertical channel transistors are formed in a lower tier of vertical channel transistors.

20. The method of claim 19, further comprising:
forming at least one upper tier of vertical channel transistors on the lower tier of vertical channel transistors by bonding at least one SOI substrate to the lower tier of vertical transistors; and
forming upper tier vertical channel transistors from an Si device layer of the at least one SOI substrate, wherein each of the at least one SOI substrate corresponds to a respective upper tier of vertical channel transistors.
